(19) United States
(12) Patent Application Publication
(10) Pub. No.: US 2021/0159906 A1
(43) Pub. Date: May 27, 2021

(54) ANALOG TO DIGITAL CONVERTER

(71) Applicant: VERVESEMI MICROELECTRONICS PRIVATE LIMITED, Greater Noida (IN)

(72) Inventors: Pratap Narayan SINGH, Greater Noida (IN); Rajeev JAIN, Greater Noida (IN); Ashish Kumar SHARMA, Greater Noida (IN); Chinmaya DASH, Greater Noida (IN)

(73) Assignee: VERVESEMI MICROELECTRONICS PRIVATE LIMITED, Greater Noida (IN)

(21) Appl. No.: 17/105,359

(22) Filed: Nov. 25, 2020

(30) Foreign Application Priority Data
Nov. 27, 2019 (IN) 201911048483

(51) Int. Cl. H03M 1/08; H03M 3/00; H03M 1/66

(52) U.S. Cl. CPC H03M 1/08; H03M 3/50; H03M 1/66; H03M 3/422; H03M 3/464; H03M 3/37

(57) ABSTRACT

A multilevel analog to digital converter (ADC) is composed of noise shaping filter and multi-level quantizer, where said quantizer is made from an array of comparators, each coupled with one reference level, the said quantizer is coupled with a thermometric digital to analog converters (DAC) in the feedback path, the said DAC output is compared with ADC input and error is fed to noise shaping filter, said reference levels of each quantizer is generated from a digital to analog converter coupled with a digital quantizer reference controller and said digital quantizer reference controller is randomly changing the reference levels in a way that quantizer coupled DAC elements are indirectly randomised to improve the overall linearity and noise performance of the converter.

### FIELD OF INVENTION

Present invention relates to the field of analog to digital conversion. Specifically, it relates to analog to digital converter with reduced loop delay. More specifically, relates to converters involving a flash converter and digital to analog converter in feedback loop of the system; with one analog input signal generating the digital output accurately representing the behaviour of the input signal in time and voltage. The current invention enables the improvement in linearity of the analog to digital converter and also signal to noise ratio in certain use case.

### BACKGROUND OF INVENTION

Analog to digital converters are key interface to the computing applications requiring the real-world data; real world analog signal is sampled using a clock to get it converted into discrete time digital signal to be used for forthcoming signal processing requirements. The fundamental requirement from this converter process is to represent the analog signal with best possible accuracy; key parameters to benchmark the accuracy of the conversion is noise and linearity in a global perspective. FIG. 1 represents a one such conventional continuous time analog to digital converter (ADC) where input analog signal is converted to digital output signal (DOUT) using quantizer array (101) which is made of one or plurality of comparators performing comparison with REFERENCE of the analog input signal produced by loop filter stages. The quantized output from the comparator array (101) is fed to the DAC (102) for generation of analog signal to be compared to the input signal and generate the error signal for the loop; error signal for the loop is zero in a certain frequency range called usable bandwidth (BW); accuracy of the analog to digital conversion is determined by the noise added by the loop and linearity of the DAC (102). The conversion linearity is determined by the loop gain and also DAC element linearity.

Inherently linear, single bit DAC's can be used inside sigma delta converters but they are not suitable for high resolution and high dynamic range requirements as they need large Oversampling ratios to meet these requirements. Therefore, multi bit DAC's are most suitable and are invariably used for such applications. However, multi bit DAC's have the problem of element mismatch and DAC linearity can be a major concern. To improve DAC linearity DEM/DWA/PR sequences are applied to the input of the DAC by employing mismatch shaping algorithms inside DEM (103). The issue with Mismatch shaper DEM (103) is that it adds extra delay in feedback loop (?) which impacts the stability of the loop. Prior art U.S. Pat. No. 6,346,898 quantizer array (101) is shown in FIG. 2 with modification to remove the DEM (103) from the feedback path and improve the stability of the loop filter. This is achieved by adding a switch matrix (201) which has plurality of switches connecting the reference voltages across all comparators; controlled by DEM (202). But quantizer array shown in FIG. 2 has limitation in terms of speed because of number of switches required to connect all comparators is N×N, where N is number of comparators. The Number of switches required increases exponentially with resolution of the quantizer. These switch transistors and their corresponding layout parasitic are limiting the settling speed of the reference voltages applied to the REF input of the comparators. This limits the maximum possible speed of the ADC in the design use case.

U.S. patent Ser. No. 10/075,181 is using segmented rotators to reduce the latency for digital code generation, but this method still produces significant delay which cannot be accepted in the wide bandwidth converters.

### OBJECTIVES OF INVENTION

Principal Object of this invention is to provide an arrangement of sigma-delta analog-to-digital converter (ADC) with reduced excess loop delay.

The other object is to provide ADC with improved linearity by noise shaping the element mismatch of the feedback DAC without impacting the loop delay.

### SUMMARY OF THE INVENTION

Analog to digital converter (ADC) is composed of noise shaping filter and multi-level quantizer, where said quantizer is made from an array of comparators, each coupled with one reference level, the said quantizer is coupled with a thermometric digital to analog converters (DAC) in the feedback path, the said DAC output is compared with ADC input and error is fed to noise shaping filter, said reference levels of each quantizer is generated from a digital to analog converter coupled with a digital quantizer reference controller and said digital quantizer reference controller is randomly changing the reference levels in a way that quantizer coupled DAC elements are indirectly randomised to improve the overall linearity and noise performance of the converter.

In one of the embodiments, the said digital reference controller is also coupled to the said quantizer outputs to further shape DAC mismatch noise based on history of previous outputs of the quantizer without adding any delay to the loop.

In other embodiment, method of randomization in digital reference controller may have noise transfer function described by (1-Z-1)2.

In other embodiment, the converter operates in a way that said noise shaping is using the comparators outputs.

The invention also provides a method of using the quantizer made of comparator arrays with reference generated from a digitally controlled DAC with comparator outputs coupled to another main DAC operating to generate analog signal.

The method, further get the reference voltages controlled by a digital controller to randomise the main DAC elements to achieve the mismatch noise shaped and improved linearity for the application, said arrangement may be used to improve linearity of the MDAC in the pipelined converters as well.

### BRIEF DESCRIPTION OF FIGURES

FIG. 1. Illustrates a block diagram of a conventional Continuous time multi bit Sigma delta Analog-to-Digital (A/D) converter known as prior art.

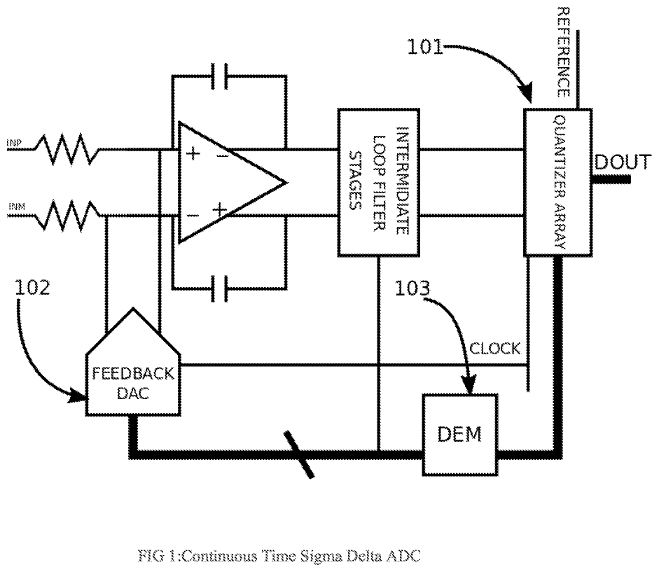

FIG. 2. Illustrates a block diagram of a multi bit Sigma delta Analog-to-Digital (A/D) converter employing Dynamic Element matching/Mismatch Shaping inside quantizer to reduce DAC element mismatch as known in the prior art.

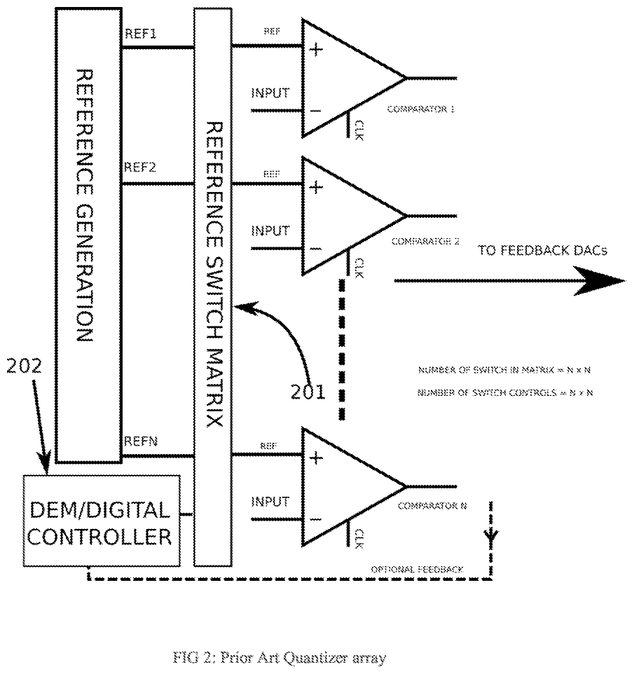

FIG. 3. Illustrates a block diagram of an embodiment of sigma-delta analog-to-digital converter employing multi bit parallel DAC based reference in accordance with the present invention.

FIG. 4. Illustrates a block diagram of one embodiment of DAC based multi-level reference generation inside sigma-delta ADC in accordance with the present invention.

FIG. 5. Illustrates a block diagram of one embodiment of DAC based multi-level reference generation inside Pipeline ADC in accordance with the present invention.

FIG. 6. Illustrates a block diagram of an example Digital Controller Implementation used for mismatch shaping.

FIG. 7. Illustrates a block diagram of an example state machine that can be used in example Digital Controller Implementation of FIG. 6.

### DETAILED DESCRIPTION OF INVENTION

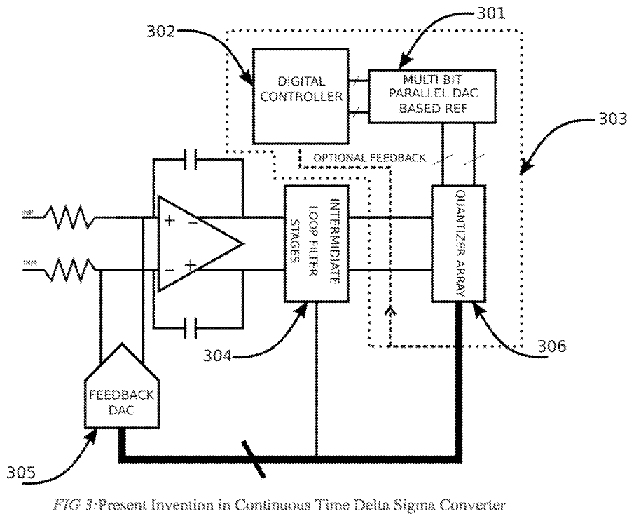

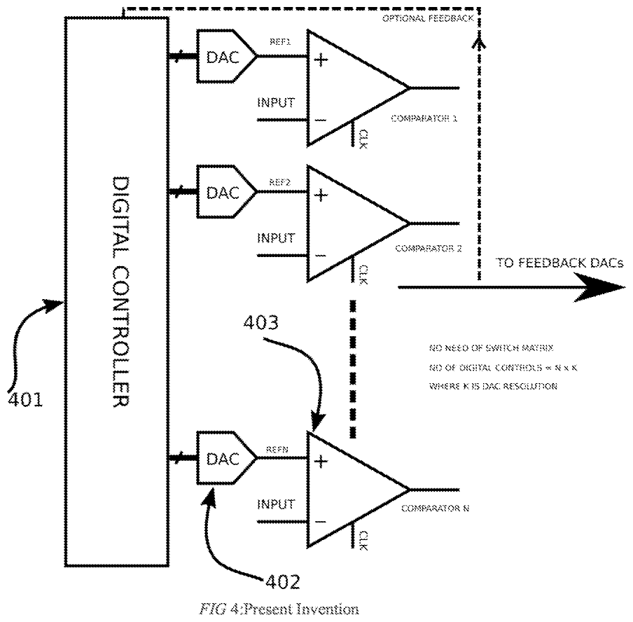

Present invention as described in FIG. 4, comprises of comparator array, made of plurality of comparators (403) with one of the input terminals coupled to the analog input coming from the Loop filter Stage (304) and other input terminal acting as a reference for comparison is coupled to a digital to analog converters DACs (402) (Reference generation DAC). Object 301 is illustrated in FIG. 4 as combination of multiple objects 401,402,403. The output of each of the plurality of comparators is directly coupled to the input of the feedback DAC (305) as shown in FIG. 3. Individual elements of reference generation DAC (402) has its digital inputs coupled to the output of the digital controller (401,301). This digital controller 401 may be also used for implementing the mismatch shaping algorithm like random rotation or DEM. The digital controller 401 generates unique codes for each of the reference DACs based on the code value the reference voltages are generated. These reference voltages act as the threshold values for each comparator 403 and the comparator compares the output of loop filter with these reference voltages and generates a digital bit stream, which is fed to each element of the feedback DAC (305). Thus, each of the comparator when applied with the predefined reference voltages as determined by the digital controller (401,301), is acting as randomizer for feedback DAC (305) hence resulting in improvement in linearity of the overall ADC (FIG. 3).

As an example of 3b quantizer and 3b feedback DAC in case of continuous time delta sigma ADC the Quantizer array consists of 7 comparators and each connected with 3b reference generation DAC on reference input. When analog input is applied to the quantizer array, 3b reference generation DAC is generating 7 different reference voltages need to generate thermometric outputs from the comparators and this output is applied to feedback DAC (305) to generate the analog feedback signal for the loop. The feedback DAC (303) can be implemented in any way e.g. if it is a current steering DAC (402) then it comprises of 7 current sources switching to produce analog output. If there is any mismatch in the current sources of the feedback DAC 305 it will result in distortion of the ADC. If desired ADC resolution is 16b then DAC (305) current source elements must match for up to 16b accuracy, which is difficult to achieve without randomisation/DWA or DEM.

Randomisation is a technique to uniformly spread the element mismatch across the spectrum by randomly selecting the elements. Techniques like Dynamic Element Matching (DEM) or data weighted averaging (DWA) shape the noise introduced by the element mismatch. However, adding any mismatch shaper in loop between Quantizer (306) and feedback DAC (305) will add excess loop delay causing stability issues of ADC loop. In the present invention a set of components indicated by block (303) enable the mismatch shaping operation without impacting the loop delay. Further, individual DAC elements of reference generation DAC (402) enable minimum parasitic load at the reference input of the comparator array. Digital controller can optionally take the feedback from the quantizer output to perform Dynamic element matching or can simply act as a randomizer by not taking any feedback from quantizer. The whole arrangement results in a much faster operation than any of the prior arts.

The complete implementation of Multi bit parallel DAC based reference (301) require N*K number of digital controls where K is reference generation DAC resolution and N is the no of comparators as against N*N in the prior art 1. Further, 301 does not need any N*N switch matrix as was needed inside 201 of prior art 1. As a result, total parasitic capacitance on reference nodes is exponentially reduced and this results in fast settling of the reference voltages and higher speed of operations can be achieved. Further, the reference generation DAC block (402) has no design restrictions and can be implemented as binary or thermometric DAC. This block 402 can easily be adapted to any of the available DAC topologies like current steering or ladder.

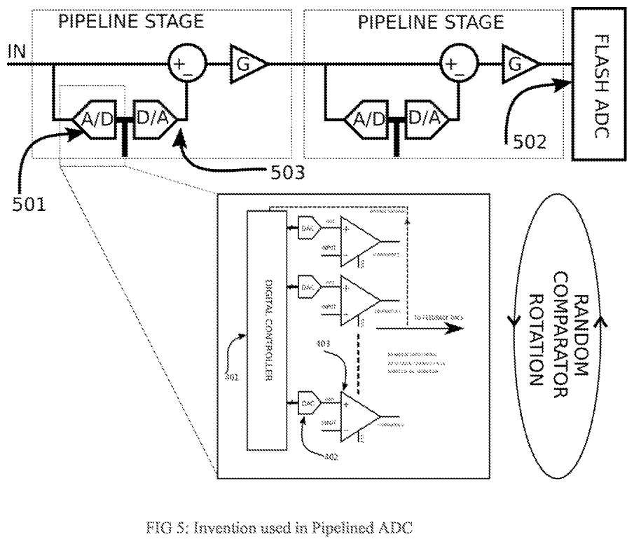

Another application of the present invention is shown in FIG. 5 where inside pipelined ADC stage, FLASH ADC (501) can be implemented as (401,402,403) then pipelined stage DAC 503 will have improved linearity as a result it will improve the SFDR and THD of the overall analog to digital conversion.

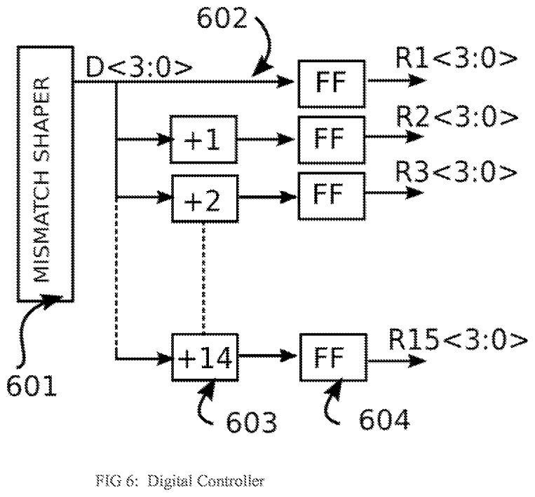

The Digital Controller 401 can use any scheme or algorithm to implement the randomized reference generation within constraints of clock timing. Amongst plurality of schemes, one example is shown in FIG. 6 for 4 bit reference generation DAC element 402. In this example, a Linear Feedback Shift Register 601 is used to generate a pseudo-random sequence with very large repetition period. Any 4 bits selected from the LFSR bus 602 can drive a feedback DAC 305 element providing one REF signal. Other N−1 feedback DACs are driven with different 4 bit numbers generated from any LFSR bits. 603 shows one such scheme where fast non-saturation constant addition circuit is used to other DAC inputs. Here each next element is generated by adding 1 to it. E.g. If R1<3:0> represents decimal 1 then R2<3:0> will represent decimal 2, R3<3:0> will represent decimal 3 and so on. The last stage flipflops 604 ensures matching delays of the inputs to DAC elements. The digital controller state machine can take a feedback from the Quantizer and can be used to generate DEM/DWA data. In this case R1<k:0> to RN<k:0> will represent DWA data and the reference voltages of comparators inside Quantizer array 306 will change as per the DEM/DWA data.

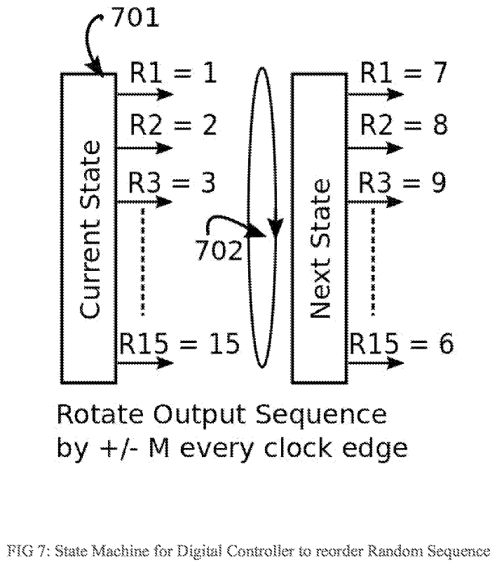

Another example scheme is shown in FIG. 7. Here Current state 701 has a sequence of outputs 1, 2, 3, 4, 5, 6, 7, 8, 9, 10, 11, 12, 13, 14, 15. The next sequence of output is obtained by rotating the present state by a value M in left or right direction 702. The value of M and direction is defined as a function of current state and feedback value from quantizer 306 output.

The Digital Controller can also be used to generate any higher order noise shaping mismatch function to address higher linearity requirements.

While the invention has been particularly described with references to preferred embodiments thereof, it will be understood by those skilled in the art that various changes may be made therein without departing from the scope of the invention encompassed by the appended claims.

We claim:

1. A multilevel analog to digital converter (ADC) comprises intermediate loop filter (304) and multi-level quantizer (306), the said quantizer is made from an array of comparators (403), each coupled with one reference level (402) and each individual reference generation directly coupled to each comparator correspondingly as multibit parallel DAC (301), said quantizer is coupled with a thermometric digital to analog converters (DAC) (305) in the feedback path, the said DAC output is compared with ADC input and error is fed to intermediate loop filter, said reference levels of each quantizer is generated from a digital to analog converter 302, 401 coupled with a digital quantizer reference controller 401 and said digital quantizer reference controller is randomly changing the reference levels in a way that quantizer coupled DAC 305 elements are indirectly randomised that is well known to improve the overall linearity and noise performance of the converter.

2. The ADC as claimed in claim 1, wherein the said digital reference controller (401) is also coupled to the said quantizer (403) outputs to further shape DAC 305 mismatch noise based on history of previous outputs of the quantizer without adding any delay to the loop

3. The ADC as claimed in claim 1, wherein said digital reference controller (401) performs the mismatch noise transfer function with multiple orders of magnitude using the previous values of the quantizer and randomising it hereafter

4. The ADC as claimed in claim 1 wherein the quantizer consists of plurality of comparators (403) each coupled with individual DAC element (402) supplying the reference of the each comparator, further the said comparator outputs coupled to feedback DAC 305 to generate analog feedback signal of the loop filter of the ADC.

5. The ADC as claimed in claim 4, wherein DAC element (402) further receives the reference voltages controlled by a digital controller (401) to randomise the main DAC elements (305) using the said quantizer outputs coupled to the said feedback DAC 305 and digital controller also coupled to DAC 301 inputs and quantizer 306 outputs while each quantizer inputs are also coupled to the intermediate loop filter stage 304 and DAC 301 outputs functions as reference input to the said quantizer 306 change of the DAC output changes the reference of the quantizer hence changing the quantizer output coupling to feedback DAC 305.
